(19) United States
(12) Patent Application Publication
(10) Pub. No.: US 2024/0306322 A1
(43) Pub. Date: Sep. 12, 2024

(54) CURVED DISPLAY PANEL AND CURVED DISPLAY DEVICE

(71) Applicant: Shenzhen China Star Optoelectronics Semiconductor Display Technology Co., Ltd., Shenzhen (CN)

(72) Inventors: Weiran CAO, Shenzhen (CN); Rong XIA, Shenzhen (CN)

(21) Appl. No.: 18/544,509

(22) Filed: Dec. 19, 2023

(30) Foreign Application Priority Data
Mar. 10, 2023 (CN) 202310254524.2

(51) Int. Cl. H05K 5/02

(52) U.S. Cl. CPC H05K 5/02

(57) ABSTRACT

A curved display device and a curved display panel are provided. The curved display panel has a first side surface and a second side surface opposite to each other, and includes a first edge, a second edge, a third edge, and a fourth edge sequentially connected end to end. The first side surface is a smooth display surface. The first edge is opposite to the third edge, the second edge is opposite to the fourth edge, the first edge and the third edge are oppositely bent towards the first side surface, and the second edge and the fourth edge are oppositely bent towards the first side surface. The first edge, the second edge, the third edge, and the fourth edge of the curved display panel sequentially intersect at four corner points, and circle center points of curvature circles corresponding to the four corner points are located at a same point.

### CROSS-REFERENCE TO RELATED APPLICATION

This application claims priority to Chinese Patent Application No. 202310254524.2, filed on Mar. 10, 2023, the disclosure of which is incorporated herein by reference in its entirety.

### TECHNICAL FIELD

The present disclosure relates to display technologies, and in particular, to a curved display panel and a curved display device.

### BACKGROUND

Current display devices in a market mainly include flat display devices and curved display devices. The curved display devices are commonly used to display wide-angle images due to their wider visual angle ranges and wider visual fields than those of the flat display devices. Meanwhile, a curved display, as a curved structure, has a curvature radius. Therefore, when a user is viewing at focus of the curved display, a visual angle of the user will be equidistant from a displayed image, which can reduce a burden on the eyes.

However, curved display devices generally adopt a one-dimensional curved surface, that is, the surface set to be curved in a horizontal dimension. From a visual sense, this structure is easy to cause users to selectively ignore display areas at four corners of the display screen or cause visual inconvenience.

### SUMMARY

The present disclosure provides a curved display panel. The curved display panel includes a first side surface and a second side surface opposite to the first side surface, wherein the first side surface is a smooth display surface. The curved display panel includes a first edge, a second edge, a third edge, and a fourth edge sequentially connected end to end, the first edge being opposite to the third edge and the second edge being opposite to the fourth edge. The first edge and the third edge are oppositely bent towards the first side surface, and the second edge and the fourth edge are oppositely bent towards the first side surface. The first edge and the second edge intersect at a first corner point, the second edge and the third edge intersect at a second corner point, the third edge and the fourth edge intersect at a third corner point, and the fourth edge and the first edge intersect at a fourth corner point. A first circle center point of a curvature circle corresponding to the first corner point, a second circle center point of a curvature circle corresponding to the second corner point, a third circle center point of a curvature circle corresponding to the third corner point, and a fourth circle center point of a curvature circle corresponding to the fourth corner point are located at a same point.

The present disclosure further provides a curved display device. The curved display device includes a supporting member and a curved display panel. The curved display panel includes a first side surface and a second side surface opposite to the first side surface, wherein the first side surface is a smooth display surface. The curved display panel includes a first edge, a second edge, a third edge, and a fourth edge sequentially connected end to end, the first edge being opposite to the third edge and the second edge being opposite to the fourth edge. The first edge and the third edge are oppositely bent towards the first side surface, and the second edge and the fourth edge are oppositely bent towards the first side surface. The first edge and the second edge intersect at a first corner point, the second edge and the third edge intersect at a second corner point, the third edge and the fourth edge intersect at a third corner point, and the fourth edge and the first edge intersect at a fourth corner point. A first circle center point of a curvature circle corresponding to the first corner point, a second circle center point of a curvature circle corresponding to the second corner point, a third circle center point of a curvature circle corresponding to the third corner point, and a fourth circle center point of a curvature circle corresponding to the fourth corner point are located at a same point. The supporting member is disposed on the second side surface of the curved display panel to support the curved display panel.

### BRIEF DESCRIPTION OF THE DRAWINGS

In order to clearly describe technical solutions in embodiments of the present disclosure, drawings used in the embodiments of the present disclosure will be simply described. Apparently, the drawings descried below are merely some of the embodiments of the present disclosure, based on the drawings, other drawings can be obtained by those skilled in the art without involving creative labors.

FIG. 1 illustrates a schematic structural diagram of a first side surface of a curved display panel according to some embodiments of the present disclosure.

FIG. 2 illustrates a schematic diagram of a test principle of a reference value Σ according to some embodiments of the present disclosure.

FIG. 3 illustrates a schematic structural diagram of a second side surface of the curved display panel according to some embodiments of the present disclosure.

List of reference numerals:

| | |
|---|---|
| Curved display panel | 100 |
| First side surface | S1 |
| Second side surface | S2 |
| First edge | 11 |
| Second edge | 12 |
| Third edge | 13 |
| Fourth edge | 14 |
| First virtual line | 101 |
| Second virtual line | 102 |
| First midpoint | Q1 |
| Second midpoint | Q2 |
| Third midpoint | Q3 |
| Fourth midpoint | Q4 |
| First corner point | C1 |
| Second corner point | C2 |
| Third corner point | C3 |
| Fourth corner point | C4 |
| Center point | O |
| Circle center point | E |
| Standard area | SA |
| Test area | T |
| Supporting member | 200 |
| Supporting strip | 201, 202, 21, 22, 23, 24 |

### DETAILED DESCRIPTION

Technical solutions in embodiments of the present disclosure will be clearly and completely described below in conjunction with accompanying drawings in the embodiments of the present disclosure. Apparently, the described embodiments are merely some of the embodiments of the present disclosure, not all of them. Based on the embodiments in the present disclosure, all other embodiments obtained by those skilled in the art without making creative efforts fall within a scope of protection of the present disclosure. Moreover, it should be understood that the specific embodiments described here are only used to describe and explain the present disclosure and are not used to limit the present disclosure. In the present disclosure, without any explanation to the contrary, directional terms used herein such as “upper” and “lower” usually refer to the upper and lower positions of a device in an actual use or working state, specifically to the directions of the figures of the accompanying drawings, and terms “inner” and “outer” refer to a profile of the device.

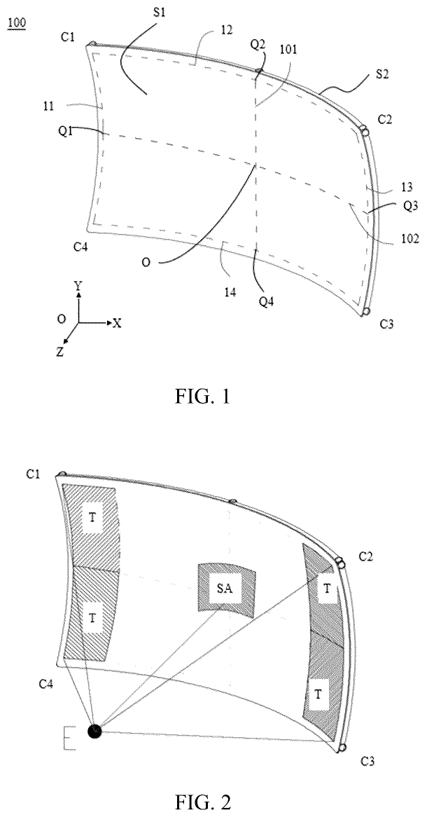

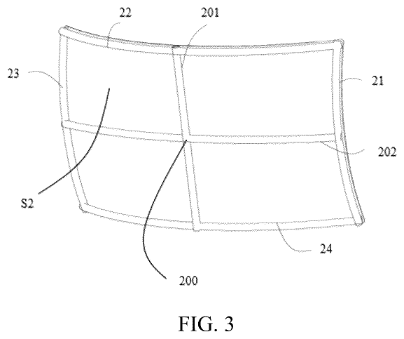

Referring to FIG. 1 to FIG. 3, in some embodiments of the present disclosure, a curved display panel 100 provided, the curved display panel 100 includes a first side surface S1 and a second side surface S2 opposite to the first side surface S1. The first side surface S1 is a display surface of the curved display panel 100, the second side surface S2 is a back surface of the curved display panel 100, and the first side surface S1 and the second side surface S2 are smooth curved surfaces.

The curved display panel 100 includes a first edge 11, a second edge 12, a third edge 13, and a fourth edge 14 sequentially connected end to end. The first edge 11 is opposite to the third edge 13, and the second edge 12 is opposite to the fourth edge 14. In some embodiments, the first edge 11 and the third edge 13 are short edges of the curved display panel 100, and the second edge 12 and the fourth edge 14 are long edges of the curved display panel 100. It can be understood that in some other embodiments, the long edges and the short edges can be exchanged.

It should be noted that in some embodiments, the first edge 11, the second edge 12, the third edge 13, and the fourth edge 14 are edges of a display area of the curved display panel 100, and infinitely close to edges of the curved display panel.

The first edge 11 and the third edge 13 are oppositely bent towards the first side surface S1, and the second edge 12 and the fourth edge 14 are oppositely bent towards the first side surface S1, which can achieve a three-dimensional curved display while making a display surface of the curved display panel 100 as a curved surface. Meanwhile, this design provides a better coverage effect for the curved display panel 100 to provide a better visual immersive experience for users.

Specifically, for convenience of the following description, a midpoint of the first edge 11 is defined as a first midpoint Q1, a midpoint of the second edge 12 is defined as a second midpoint Q2, a midpoint of the third edge 13 is defined as a third midpoint Q3, and a midpoint of the fourth edge 14 is defined as a fourth midpoint Q4; meanwhile, an intersection of the first edge 11 and the second edge 12 is defined as a first corner point C1, an intersection of the second edge 12 and the third edge 13 is defined as a second corner point C2, an intersection of the third edge 13 and the fourth edge 14 is defined as a third corner point C3, and an intersection of the fourth edge 14 and the first edge 11 is defined as a fourth corner point C4.

The curved display panel 100 further includes a first virtual line 101 and a second virtual line 102 located on the first side surface S1, and an intersection of the first virtual line 101 and the second virtual line 102 is a center point O of the first side surface S1. The first virtual line 101 connects the midpoint of the second edge 12 and the midpoint of the fourth edge 14, that is, two ends of the first virtual line 101 are the second midpoint Q2 and the fourth midpoint Q4, respectively. The second virtual line 102 connects the midpoint of the first edge 11 and the midpoint of the third edge 13, that is, two ends of the second virtual line 102 are the first midpoint Q1 and the third midpoint Q3, respectively.

For better description, the center point O is taken as an origin, a horizontal direction of the curved display panel during use is taken as a horizontal axis, and a vertical direction of the curved display panel during use is taken as a vertical axis, to thereby establish a three-dimensional coordinate system, and a coordinate of the center point O is defined as (0, 0, 0).

In some embodiments, the first virtual line 101 is a straight line, and the second virtual line 102 is a curved line. Thus, the first virtual line 101 is located on the vertical axis, a coordinate of the first midpoint Q1 is (−x, 0, z), a coordinate of the second midpoint Q2 is (0, y, 0), a coordinate of the third midpoint Q3 is (x, 0, z), and a coordinate of the fourth midpoint Q4 is (0,−y, 0); and a coordinate of the first corner point C1 is (−x, y, z), a coordinate of the second corner point C2 is (x, y, z), a coordinate of the third corner point C3 is (x,−y, z), and a coordinate of the fourth corner point C4 is (−x,−y, z); wherein x>0, y>0, and z>0, and sizes of x, y, and z are determined by lengths of the long edges and the short edges of the first side surface S1/the display surface and a degree of curvature of the display surface of the curved display panel 100.

A coordinate of one point in the first side surface S1 is defined as (a, b, c), thus −x≤a≤x,−y≤b≤y, and 0≤c≤z.

According to the above coordinate system, a coordinate of one point located on the first edge 11 is (−x, b, c), and a corresponding curvature radius is defined as R1b; a coordinate of one point located on the second edge 12 is (a, y, c), and a corresponding curvature radius is defined as R2a; a coordinate of one point located on the third edge 13 is (x, b, c), and a corresponding curvature radius is defined as R3b; a coordinate of one point located on the fourth edge 14 is (a,−y, c), and a corresponding curvature radius is defined as R4a; and a coordinate of one point located on the second virtual line 102 is (a, 0, c), and a corresponding curvature radius is defined as R5a.

In some embodiments, a value of the curvature radius R1b and a value of the curvature radius R3b respectively gradually decrease with increases in absolute values |b| of vertical ordinates of corresponding points (−x, b, c) and (x, b, c); a value of the curvature radius R2a and a value of the curvature radius R4a respectively gradually decrease with increases in absolute values |a| of horizontal ordinates of corresponding points (a, y, c) and (a,−y, c); and a value of the curvature radius R5a gradually decreases with an increase in an absolute value |a| of a horizontal ordinate of a corresponding point (a, 0, c). That is, in the first side surface S1, curvature radii of points on one of the first edge 11, the second edge 12, the third edge 13, and the fourth edge 14 gradually increase along a direction towards the midpoint the one of the first edge 11, the second edge 12, the third edge 13, and the fourth edge 14.

In some embodiments, in the first side surface S1, a straight line with the center point O as a starting point ends at a point on one of the first edge 11, the second edge 12, the third edge 13, and the fourth edge 14, and curvature radii of points on the straight line gradually increase along a direction towards the center point O.

It can be understood that the larger a value of a corresponding curvature radius of one point, the smoother a position of a curved surface corresponding to the one point is. That is, in the embodiments, a middle part of the curved display panel 100 is smoother than four corner parts of the curved display panel 100. Meanwhile, the first virtual line 101 is a straight line, thus a corresponding curvature radius of each point on the first virtual line 101 is close to infinity.

In some embodiments, in the first side surface S1, a corresponding curvature radius of a point (a, b, c), a corresponding curvature radius of a point (a,−b, c), a corresponding curvature radius of a point (−a,−b, c), and a corresponding curvature radius of a point (−a, b, c) are equivalent. That is, the curved display panel 100 is symmetrically designed with respect to each of the first virtual line 101 and the second virtual line 102.

In some embodiments, in the first side surface S1, circle center points of curvature circles respectively corresponding to the first corner point C1, the second corner point C2, the third corner point C3, and the fourth corner point C4 are located on a same point. The circle center points (i.e., the same point) is defined as E, in the embodiments, a coordinate of the circle center point E is (0, 0, m), and m>0. That is, a connecting line of the center point O and the circle center point E is perpendicular to the first virtual line 101. This design makes the curved surface of the curved display panel 100 as a “dome” curved surface, provides a better visual immersive experience for users, while avoiding the users to selectively ignore display areas in four corners of a display screen or to cause visual inconvenience.

In some embodiments, when designing the curved surface of the curved display panel 100, in order to give consideration to a best viewing angle and a good quality of the panel, curvatures of the first virtual line 101 and the second virtual line 102 are specially designed. Specifically, in the embodiments, R5a=Σ*L*R2a, L represents an edge length of the first edge 11 or the third edge 103, and Σ represents a reference value for a corresponding value of L.

In some embodiments, before producing the panel, in order to give consideration to both the quality of the panel and a best viewing angle, display panels with different sizes are tested by conducting an experiment based on visual and optical angles to obtain a relationship between the reference value Σ and the edge length L. In the experiment, the circle center point E is taken as a measurement point to place an optical device, such as an optical camera, parameters such as brightness, viewing angle, color difference, and color temperature of each point on the panel are measured through the optical device, the parameters are made infinitely close to or equal to standard values to obtain a current relationship between the reference value Σ and the edge length L.

In some embodiments, a method for testing the display panel may include the following operations.

Firstly, the center point O of the panel is taken as a center to select a standard area (SA) about 100 millimeters (mm)*100 mm. A certain number of measuring points are randomly selected in the standard area SA, for example, five points (generally one point at each of four corners and one point at the center thereof). One or more parameters (such as brightness, viewing angle, color difference, and color temperature corresponding to the five points) are measured by an optical device, average values of the above parameters of the five points are calculated, and the average values are taken as standard values.

Then, four test areas T are selected at the four corners of the panel. Four corner points C1, C2, C3, and C4 correspond to corner points of the four test areas T, respectively. An area of each test area T can be selected as 10 mm*10 mm or 20 mm*20 mm. For each test area T, similar to the standard area SA, one or more corresponding parameters (such as brightness, viewing angle, color difference, and color temperature of a certain number of measuring points (e.g., five points)) of the test area T are measured, and average values of the above parameters of the measured points are calculated, and the average values are taken as test values. It should be noted that the corner points C1/C2/C3/C4 of the display panel corresponding to the test areas T must be taken as one of the measuring points of the corresponding test areas T.

Meanwhile, each test value is compared with a corresponding standard value to obtain a compared result. A degree of curvature of the panel is continuously adjusted based on the compared result, until a value of the each test value is close to or equal to the corresponding standard value. At this time, the test areas T and the standard area SA have equal brightness, no color difference, consistent color temperature, and consistent viewing angle, that is, a picture quality at O is substantially the same as that of the four corners C1, C2, C3 and C4.

Then, a size of the display panel is changed, and the above operations are repeated, to thereby obtain the relationship between the reference value Σ and the edge length L. It should be noted that when comparing the test values with the standard values, it is also necessary to test whether a stress of the display panel is within a quality guarantee range, to avoid screen fragmentation caused by excessive bending in a design process, or to avoid that excessive flatness cannot meet requirements of the viewing angle.

In some embodiments, the relationship between the reference value Σ and the edge length L is obtained according to the experiment, and the relationship is shown in the following table.

| A range of the corresponding value L | Reference value Σ |
|---|---|
| 300 mm ≤ L ≤ 500 mm | 0.004 |
| 500 mm ≤ L ≤ 800 mm | 0.003 |
| 800 mm ≤ L | 0.0025 |

Compared to a one-dimensional curved design in the related art, opposite edges of the curved display panel 100 in the embodiments of the present disclosure are oppositely bent towards the display surface, which can achieve a multi-dimensional curved display, thus providing the better coverage effect for the curved display panel 100 to provide better visual immersive experience for users.

Meanwhile, in some embodiments of the present disclosure, the circle center points of the curvature circles corresponding to the four corner points of the curved display panel 100 are located at the same point, which makes the curved surface of the curved display panel 100 as the “dome” curved surface, which provides better visual immersive experience for the users, while avoiding the users to selectively ignore display areas at four corners of the display screen or to cause visual inconvenience.

Moreover, in some embodiments of the present disclosure, the first virtual line 101 of the curved display panel 100 adopts the straight line, and the second virtual line 102 adopts the curved line. Meanwhile, a size relationship between the curvature radius R5a of a corresponding point on the second virtual line 102 and the curvature radius R2a of a corresponding point on the second edge 12 is R5a=Σ*L*R2a, wherein L represents the edge length of the first edge 11 or the third edge 13, and Σ represents the reference value for the corresponding value L. This design can give consideration to the quality of the panel and the best viewing angle, and optimize the visual effect of the panel to the greatest extent while ensuring the quality of the panel.

Based on a same inventive concept, some embodiments of the present disclosure further provide a display device. The display device includes a supporting member 200 and the curved display panel 100 of the above embodiments. The supporting member 200 is disposed on the second side surface S2 of the curved display panel 100 to support and shape the curved display panel 100.

In some embodiments, the supporting member includes at least six supporting strips. Taking the supporting member including six supporting strips as an example, the six supporting strips are disposed respectively corresponding to the first edge 11, the second edge 12, the third edge 13, the fourth edge 14, the first virtual line 101, and the second virtual line 102. Specifically, a supporting strip corresponding to the first edge 11 is named as a supporting strip 21, a supporting strip corresponding to the second edge 12 is named as a supporting strip 22, a supporting strip corresponding to the third edge 13 is named as a supporting strip 23, a supporting strip corresponding to the fourth edge 14 is named as a supporting strip 24, a supporting strip corresponding to the first virtual line 101 is named as a supporting strip 201, and a supporting strip corresponding to the second virtual line 102 is named as a supporting strip 202. The support strip 201 and the curved display panel 100 can be assembled in a fully fitted mode or in a specific point contact mode, as long as the support and shaping requirements for the curved display panel 100 can be achieved.

In summary, although the present disclosure has been disclosed in the embodiments, it can be understood that various embodiments can be combined arbitrarily, the above embodiments are not intended to limit the present disclosure. Those skilled in the art can make various modifications and embellishments without departing from a spirit and a scope of the present disclosure. Therefore, a scope of protection of the present disclosure is subject to a scope defined in the claims.

What is claimed is:

1. A curved display panel, comprising:
a first side surface and a second side surface opposite to the first side surface, wherein the first side surface is a smooth display surface; and
a first edge, a second edge, a third edge, and a fourth edge sequentially connected end to end, the first edge being opposite to the third edge and the second edge being opposite to the fourth edge,
wherein the first edge and the third edge are oppositely bent towards the first side surface, and the second edge and the fourth edge are oppositely bent towards the first side surface,
the first edge and the second edge intersect at a first corner point, the second edge and the third edge intersect at a second corner point, the third edge and the fourth edge intersect at a third corner point, and the fourth edge and the first edge intersect at a fourth corner point,
a first circle center point of a curvature circle corresponding to the first corner point, a second circle center point of a curvature circle corresponding to the second corner point, a third circle center point of a curvature circle corresponding to the third corner point, and a fourth circle center point of a curvature circle corresponding to the fourth corner point are located at a same point.

2. The curved display panel according to claim 1, further comprises a first virtual line connecting a midpoint of the second edge and a midpoint of the fourth edge and a second virtual line connecting a midpoint of the first edge and a midpoint of the third edge,
wherein the first virtual line and the second virtual line are disposed on the first side surface, an intersection of the first virtual line and the second virtual line is a center point of the first side surface, and
the curved display panel is symmetrically designed with respect to each of the first virtual line and the second virtual line.

3. The curved display panel according to claim 2, wherein:
in the first side surface, a straight line with the center point as a starting point ends at a point on one of the first edge, the second edge, the third edge, and the fourth edge; and
curvature radii of points on the straight line gradually increase along a direction towards the center point.

4. The curved display panel according to claim 2, where in the first side surface, curvature radii of points on one of the first edge, the second edge, the third edge, and the fourth edge gradually increase along a direction towards the midpoint of the one of the first edge, the second edge, the third edge, and the fourth edge.

5. The curved display panel according to claim 2, wherein the first virtual line is a straight line, and the second virtual line is a curved line.

6. The curved display panel according to claim 5, wherein curvature radii of points on the second virtual line gradually increase along a direction towards the center point.

7. The curved display panel according to claim 6, wherein a connecting line of one of the first circle center point, the second circle center point, the third circle center point, and the fourth circle center point and the center point is perpendicular to the first virtual line.

8. The curved display panel according to claim 7, wherein:
the center point is taken as an origin and the first virtual line is taken as an ordinate to define a three-dimensional coordinate system,
in the three-dimensional coordinate system, ordinates of points on the second edge are the same and ordinates of points on the second virtual line are the same,
a curvature radius of one of the points on the second edge is defined as R2a, a curvature radius of one of the points on the second virtual line with a same horizontal ordinate as the one of the points on the second edge is defined as R5a, a relationship between R5a and R2a is: R5a=Σ*L*R2a, wherein L represents an edge length of the first edge, and Σ represents a reference value for a corresponding value of L.

9. The curved display panel according to claim 8, wherein:
when 300 mm≤L≤500 mm, Σ=0.004;
when 500 mm≤L≤800 mm, Σ=0.003; or
when 800 mm≤L, Σ=0.0025.

10. A curved display device, comprising a supporting member and a curved display panel, wherein:
the curved display panel, comprises:
a first side surface and a second side surface opposite to the first side surface, wherein the first side surface is a smooth display surface; and
a first edge, a second edge, a third edge, and a fourth edge sequentially connected end to end, the first edge being opposite to the third edge and the second edge being opposite to the fourth edge,
wherein the first edge and the third edge are oppositely bent towards the first side surface, and the second edge and the fourth edge are oppositely bent towards the first side surface,
the first edge and the second edge intersect at a first corner point, the second edge and the third edge intersect at a second corner point, the third edge and the fourth edge intersect at a third corner point, and the fourth edge and the first edge intersect at a fourth corner point,
a first circle center point of a curvature circle corresponding to the first corner point, a second circle center point of a curvature circle corresponding to the second corner point, a third circle center point of a curvature circle corresponding to the third corner point, and a fourth circle center point of a curvature circle corresponding to the fourth corner point are located at a same point; and
the supporting member is disposed on the second side surface of the curved display panel to support the curved display panel.

11. The curved display device according to claim 10, further comprises a first virtual line connecting a midpoint of the second edge and a midpoint of the fourth edge and a second virtual line connecting a midpoint of the first edge and a midpoint of the third edge,
wherein the first virtual line and the second virtual line are disposed on the first side surface, an intersection of the first virtual line and the second virtual line is a center point of the first side surface, and
the curved display panel is symmetrically designed with respect to each of the first virtual line and the second virtual line.

12. The curved display device according to claim 11, wherein:
in the first side surface, a straight line with the center point as a starting point ends at a point on one of the first edge, the second edge, the third edge, and the fourth edge; and
curvature radii of points on the straight line gradually increase along a direction towards the center point.

13. The curved display device according to claim 11, where in the first side surface, curvature radii of points on one of the first edge, the second edge, the third edge, and the fourth edge gradually increase along a direction towards the midpoint of the one of the first edge, the second edge, the third edge, and the fourth edge.

14. The curved display device according to claim 11, wherein the first virtual line is a straight line, and the second virtual line is a curved line.

15. The curved display device according to claim 14, wherein curvature radii of points on the second virtual line gradually increase along a direction towards the center point.

16. The curved display device according to claim 15, wherein a connecting line of one of the first circle center point, the second circle center point, the third circle center point, and the fourth circle center point and the center point is perpendicular to the first virtual line.

17. The curved display device according to claim 16, wherein:
the center point is taken as an origin and the first virtual line is taken as an ordinate to define a three-dimensional coordinate system,
in the three-dimensional coordinate system, ordinates of points on the second edge are the same and ordinates of points on the second virtual line are the same,
a curvature radius of one of the points on the second edge is defined as R2a, a curvature radius of one of the points on the second virtual line with a same horizontal ordinate as the one of the points on the second edge is defined as R5a, a relationship between R5a and R2a is: R5a=Σ*L*R2a, wherein L represents an edge length of the first edge, and Σ represents a reference value for a corresponding value of L.

18. The curved display device according to claim 17, wherein:
when 300 mm≤L≤500 mm, Σ=0.004;
when 500 mm≤L≤800 mm, Σ=0.003; or
when 800 mm≤L, Σ=0.0025.
